(19) United States
(12) Patent Application Publication
(10) Pub. No.: US 2012/0154983 A1
(43) Pub. Date: Jun. 21, 2012

(54) Method of Fabrication of Carbon Nanofibers on Nickel Foam

(75) Inventors: Yuegang Zhang, Cupertino, CA (US); Yi Cui, Stanford, CA (US); James McDonough, San Jose, CA (US); Jang Wook Choi, Daejeon (KR)

(73) Assignee: The Regents of the University of California, Oakland, CA (US)

(21) Appl. No.: 13/267,559

(22) Filed: Oct. 6, 2011

Related U.S. Application Data
(60) Provisional application No. 61/391,313, filed on Oct. 8, 2010.

(51) Int. Cl. H01G 9/004; C23C 16/26; B32B 3/26; B05D 5/12; C23C 16/40; B82Y 40/00

(52) U.S. Cl. 361/502; 427/79; 428/319.1; 977/891

(57) ABSTRACT

A method for forming a novel composite of carbon nanofibers grown on a nickel foam is described wherein the composite, when used in a capacitor exhibits superior change retention and discharge capacities. Once the composite material has been obtained, it may be formed into electrodes which can be used to form supercapacitors of large per area capacitances in the order of 1.2 F/cm².

### CROSS REFERENCE TO RELATED APPLICATIONS

This application clams priority to U.S. Provisional Application Ser. No. 61/391,313, filed Oct. 8, 2010, which provisional application is incorporated by reference as if set forth in its entirety.

### STATEMENT OF GOVERNMENTAL SUPPORT

The inventions described and claimed herein were made in part utilizing funds supplied by the U.S. Department of Energy under Contract No. DE-AC02-05CH11231 between the U.S. Department of Energy and the Regents of the University of California for the management and operation of the Lawrence Berkeley National Laboratory. The government has certain rights in these inventions. The inventions described and claimed herein were also made in part utilizing funds under KAUST Award No. KUS-11-001-12. The government of Saudi Arabia may have certain non-exclusive, non commercial licensing rights in Saudi Arabia.

### FIELD OF INVENTION

This invention relates generally to supercapacitors, and more specifically to supercapacitors made from a novel composite of carbon nanofibers grown on a nickel foam, as well as to a novel method for forming such carbon nanofiber-nickel foam composites.

### BACKGROUND OF THE INVENTION

Supercapacitors (SCs) are useful in various applications requiring quick releases of stored energy, such as in hybrid energy systems in vehicles, digital telecommunication systems, uninterrupted power supplies (UPS) for computers, and pulsed laser techniques, due to their high power densities (>10 kW/kg), long cycle lives (>10⁶ cycles), and safe operation. In order to improve the performance of carbon-based SCs, carbon nanofibers (CNFs) and carbon nanotubes (CNTs) have been intensely studied in recent years due to their efficient ion diffusion pathways¹⁻⁶. Although some of these CNF SCs achieve relatively high specific capacitances of >100 Farads/g, the mass loading is often very low, resulting in a capacitance per area in the mF/cm² range. For applications such as small scale electronics or stationary energy storage devices, the amount of energy stored per area is more important than energy per mass.

### SUMMARY OF THE INVENTION

Described hereinafter is a supercapacitor (SC) device having large per-area capacitances made utilizing three dimensional (3D) porous substrates. Solid carbon nanofibers (CNFs) functioning as active SC electrodes are grown on a 3D metal sponge like foam, which in one embodiment is a nickel foam. The 3D porous substrates facilitate a mass loading of active electrodes and per-area capacitance of as large as 60 mg/cm² and 1.2 F/cm², respectively. Supercapacitor performance is optimized by an annealing-free CNF growth process that in the case of a nickel foam minimizes undesirable nickel carbide formation. The superior per-area capacitances obtained suggest that 3D porous substrates are useful in various energy storage devices in which per-area performance is critical.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a flow chart of a method for forming CNF on Nickel foam according to an embodiment of this invention.

FIG. 2(a) is a photograph of Ni foam before and after CNF growth. FIG. 2(b) is a SEM image of Ni foam before CNF growth, and FIGS. 2(c) and 2(d) are SEM images after CNF growth, confirming that a conformal layer of CNFs coats the Ni foam without blocking the large voids of the foam.

FIG. 3(a) is a cartoon cross section of a nickel foam cell illustrating what is believed to be the controlled outward diffusion of Ni through cracks/openings in a deposited alumina layer, which layer minimizes Ni₃C formation during CNF growth. FIG. 3(b) is a SEM image showing the originally solid Ni backbone, becoming hollow for the alumina-coated samples during growth as shown in FIG. 3(c), but remaining solid and transforming to Ni₃C for non-coated samples as shown in FIG. 3(d).

FIGS. 4(a)-(e) comprise a series of plots of measured variables and their relationship to various performance and behavioral characteristics/properties of tested supercapacitor cells made according to the methods of this invention.

FIGS. 5(a) and (b) are TEM images of (a) small and (b) large CNFs, confirming the presence of a graphitic CNF structure and suggesting that the thermal CVD synthesis yields only CNFs, rather than carbon nanotubes.

FIG. 6 (a) is a Nyquist plot indicating an internal electrode resistance of 2.5 Ω (as indicated by the x-intercept). The resistance inside the pores of the carbon nanofibers (CNFs) is calculated by subtracting the vertical asymptote (4 Ω) from the x-intercept (2.5 Ω) which results in a resistance of 1.5 φ. FIG. 6(b) is a plot of capacity retention and coulombic efficiency over 3,000 cycles for a CNF-based supercapacitor made according to the methods of this invention, both values remaining high, indicating a stable device.

### DETAILED DESCRIPTION

By way of this invention, three-dimensional (3D) porous metallic foam substrates are employed to address the areal energy storage problems of current SC devices. It has been found that active CNF materials can be loaded onto, or grown from a highly conductive 3D metallic backbone, such as Nickel, allowing for a higher mass loading of active materials per area than would otherwise be achievable with a simple 2D flat substrate. Other porous metallic foam structures such as Copper, Cobalt, and the like may potentially be used as catalysts for CNF growth. So far, 3D porous substrates have been limited to the area of Li-ion-batteries^{7,8}. Expanding their usage to SC devices brings parallel advantages to address the issues of per-area energy and power densities in SC devices.

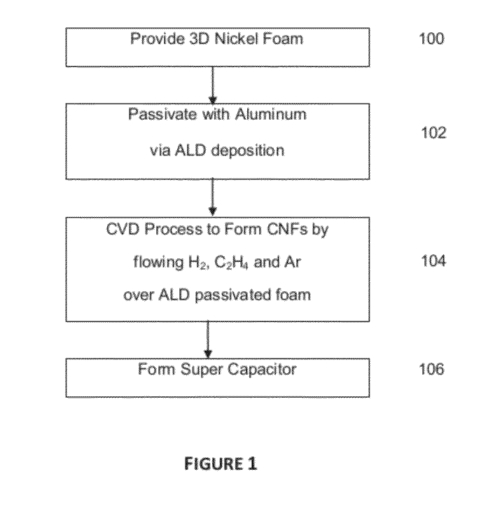

According to the novel methods developed and described herein, preparation of the CNF-based SC electrodes consists of two steps. In the first, a piece of a metal foam such as a Nickel foam (Ni foam 95% porosity, 500 g/m² surface area, from MarkeTech International) is conformally coated with one or more atomic layers of alumina (in one embodiment the layer(s) being about 1 nm thick) using an atomic layer deposition reactor. See FIG. 1, steps 100 and 102. The alumina layer serves two purposes. First, the buffering alumina layer protects the Ni foam backbone from being transformed into undesirable Ni₃C by inhibiting the diffusion of the carbon precursor into the Ni. Second, the alumina layer circumvents oxidation-reduction steps normally required for CNF growth processes. In other non-limiting embodiments of the invention, other methods of creating thin films can be used to deposit the alumina layer such as electroless plating, chemical solution deposition (the sol-gel process), or dip-coating.

Planar Ni catalysts prefer planar carbon layer growth instead of CNFs due to a lack of non-planar nucleation sites during a chemical vapor deposition (CVD) process. Therefore, in most thermal CVD CNF growth processes, an annealing step is normally needed to roughen the planar Ni surface and to prevent planar carbon layer formation. Because this annealing step is done in air, a subsequent reduction step in H₂ is required to reduce the nickel oxide back to metallic Ni. With the thin alumina layer, however, the growth process can be simplified to a single annealing-free step because the porous alumina layer helps the nucleation and growth of CNFs and prevents planar carbon growth.

The CNF growth process according the present invention is performed by flowing a gas mixture of H₂ and C₂H₄ in argon over the alumina-coated Ni foam at an elevated temperature. In an exemplary embodiment, 50 sccm H₂, 25 sccm C₂H₄, and 75 sccm Ar were flowed over the alumina-coated Ni foam substrate maintained in a tube furnace at 470° C. for 30 minutes (FIG. 1, step 104). The process is also successful at temperatures as low as 440° C., but to achieve the same mass loading of CNFs after growth as at 440° C., the growth time should be increased to approximately 1 hour. Notably, the time required to form the CNF can range from 10 minutes to an hour or more. It has been observed that early fiber growth is faster than later fiber growth, and after a period of time, fiber growth essentially ceases. Thus longer process times generally are not required, and it has been found that process times of around 20 to 30 minutes are more than sufficient to achieve desirable CNF growth.

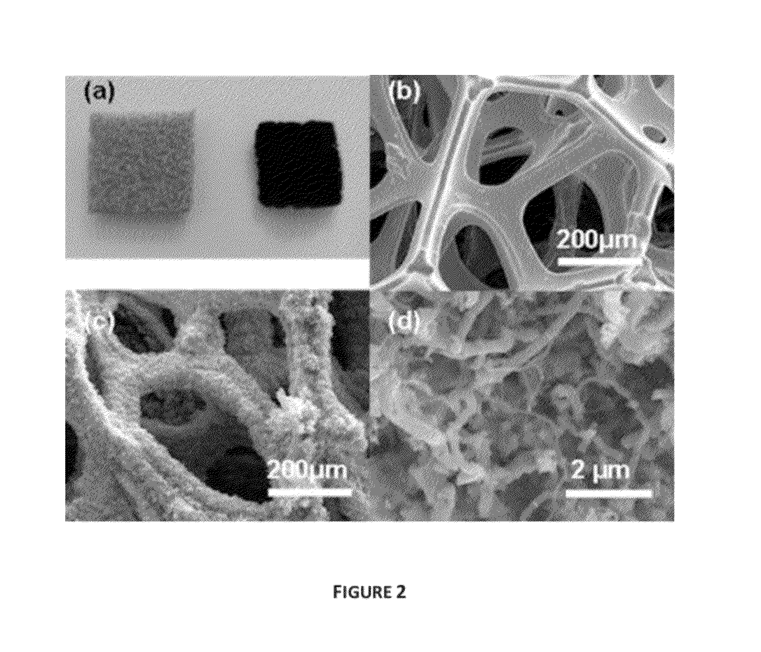

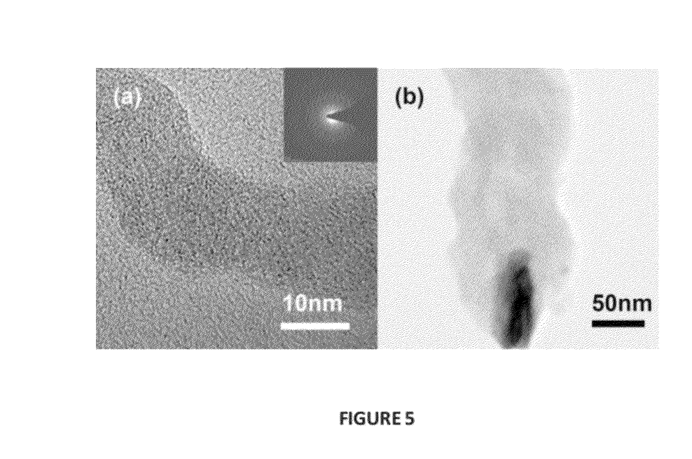

FIG. 2(a) is a photograph comparing Ni foam before and after CNF growth. The originally silver colored Ni foam changes to a uniform black color with the backbone and large voids in the foam still visible. This observation suggests a uniform CNF coating on the Ni foam, as confirmed by the SEM images before [FIG. 2(b)] and after CNF growth [FIGS. 2(c), (d)]. Uniform CNF coverage enables the entire 3D structure of the Ni foam after CNF growth to contribute to supercapacitor performance. The electrolyte solution later used in the assembly of the SC can easily penetrate the large voids in the Ni foam and contribute to the double-layer capacitance on the CNF surface throughout the entire 3D Ni foam network. TEM images of fibers (such as shown in FIG. 5) indicate that thermal CVD growth results in only CNF growth rather than CNT growth.

Three novel and synergistic aspects of this synthesis procedure are noteworthy. First, the alumina coating on the Ni foam prior to the initiation of the CNF growth process minimizes the formation of Ni₃C, a highly brittle material within the Ni foam backbone. The minimized Ni₃C formation is likely due to the alumina functioning as a buffer layer. During the growth process, which generally can be conducted above 440° C., and in an illustrated embodiment is conducted at 470° C., the alumina layer controls the ethylene decomposition and inward carbon diffusion. The temperature range is not critical, but is should be high enough such that H₂ can reduce Nickel oxide back to Nickel metal during growth, and the temperature must be high enough for the C₂H₄ to decompose into Carbon to grow the fibers.

ALD was chosen as the process of choice for the formation of the alumina layer due to the thin nature of the layer. By way of example, in ALD the alumina layer is laid down one atomic layer at a time, with the deposition steps repeated until a film of the desired thickness is achieved. In an embodiment of the invention, it has been found that Alumina film layer thickness of 1-10 nm to be suitable for the processes of this invention. As few as 3 ALD cycles is enough to produce a sufficient alumina layer. One hundred cycles was also found to work, however, the fewer cycles needed the better. Each alumina ALD cycle at 150° C. added 0.91 angstroms/cycle to overall alumina layer thickness. In a preferred embodiment, the alumina layers are deposited to a thickness of 9-10 nm. Generally, while the films should be conformal, film thickness and uniformity are not critical.

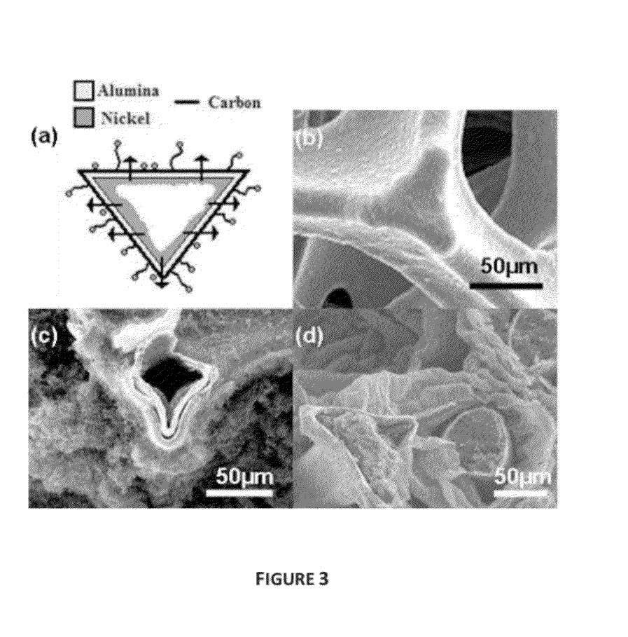

Ni as it diffuses out through the deposited alumina layer forms catalytic Ni particulates, and thus works as a catalyst for the CNF growth [FIG. 3(a)]. It is believed Ni diffusion is able to occur through the alumina layer due to small cracks or pores formed in the alumina layer during heating. This is suggested by a direct comparison with the non-coated samples. While the Ni backbone begins as solid [FIG. 3(b)] for the alumina-coated samples, the controlled outward Ni diffusion through the alumina buffer layer [FIG. 3(a)] leaves a hollow backbone structure after CNF growth [FIG. 3(c)]. When Alumina is not used, the nickel backbone remains solid and transforms to Ni₃C for non-coated samples [FIG. 3(d)] upon direct exposure to ethylene gas. In fact, a mass increase of only 60 mg/cm² during CNF growth was observed for alumina-coated Ni foam samples compared to a 108 mg/cm² increase for samples without alumina. The prevention of Ni₃C formation is responsible for the nearly 50% mass difference during growth of coated vs. non-coated samples. One skilled in the art will recognize that Ni₃C, being brittle, is not desirable for device construction, deteriorates SC performance, and contributes dead weight to the device.

This difference is also reflected in the disparate mechanical properties of the two samples. The alumina-coated samples, with minimal Ni₃C, are far less brittle than the Ni₃C-rich non-coated samples. Thus, the alumina coating helps protect the Ni foam backbone from being converted to Ni₃C. Second, the passivation with the alumina layer and H₂ flow during CNF growth make a normally required annealing step unnecessary.

For CNF growth, Ni particulates must be formed to act as catalytic nucleation and growth sites⁹. These particulates are normally formed by exposing a planar Ni catalyst to a high temperature annealing step in air followed by a subsequent H₂ reduction step to reform metallic Ni from nickel oxide. The result of the oxidation-reduction process is a roughened Ni surface which inhibits parasitic planar carbon formation during CNF growth. In the case of the present invention, however, the entire process consists of only a single CVD growth step (FIG. 1, step 104). It is believed that presence of H₂ gas flow during CNF growth acts as a reducing agent and enables direct exposure and reduction of the native oxide layer on the Ni foam via cracks and pores through the alumina film.

Finally, the temperature required for the overall process is lower than that required for normal CNF and CNT thermal chemical vapor deposition (CVD) growth processes. CVD methods for CNF and CNT growth alike with non-alloy catalysts generally require higher temperatures (545° C.-1000° C.)¹⁰. Consequently, the alumina passivation not only circumvents the annealing step but also lowers the overall process temperature significantly.

In a final step, FIG. 1, step 106, the composite CNF—Ni foam material is used in the fabrication of a SC. The SC cells in one embodiment of the invention are comprised of symmetric CNF/Ni foam electrodes and a filter paper separator, immersed in a 2 M Li₂SO₄ aqueous electrolyte solution. Other possibly suitable electrolyte solutions include KOH and Na₂SO₄.

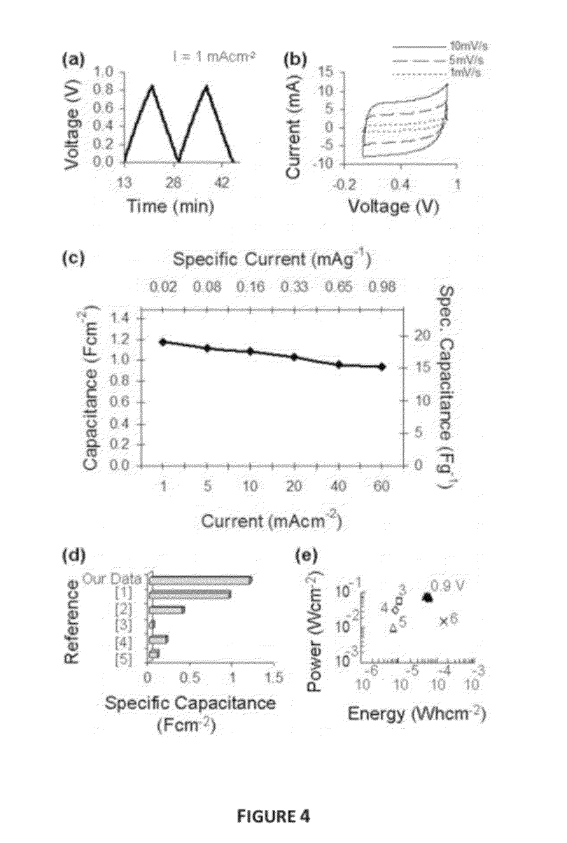

With reference to FIG. 4(a), a voltage profile for a SC device prepared using the CNF-Ni foam material of the invention under a 1 mA/cm² current density is shown. The internal cell resistance calculated by the IR voltage drop in the curve was found to be 2.5 Ω. This internal resistance value is also consistent with the internal resistance calculated by electrochemical impedance spectroscopy which also indicates a resistance of 1.5 Ω inside the pores between adjacent CNFs. The ideal triangular shape of the charging and discharging curves is evidence that capacity is due only to double-layer charging and not side reactions. Further evidence of the absence of side reactions in the instant devices is provided by cyclic voltammograms which approach ideal rectangular behavior with no redox peaks [FIG. 4(b)].

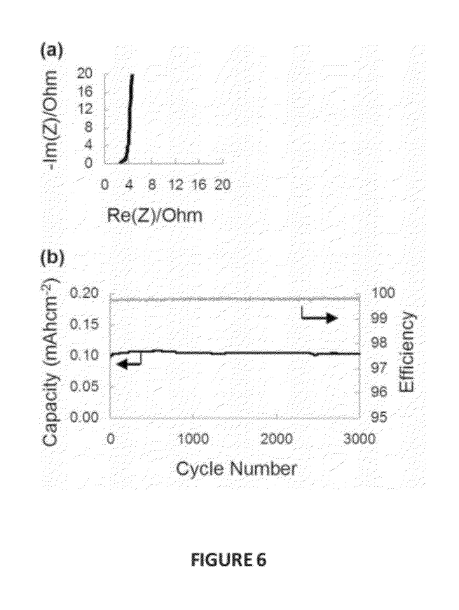

FIG. 4(c), a plot of current vs. capacitance for tested samples, exhibiting a very shallow slope, and thus illustrating that supercapacitor performance of SCs of the invention do not significantly degrade in higher power operations, due to highly efficient ion diffusion pathways. Note that while the specific currents in FIG. 4(c) are low due to the high CNF mass loading in the devices, the nominal current densities are high (1 mA/cm² to 60 mA/cm²). FIG. 4(d) is a bar graph comparing per-area capacitance data of samples tested between 0 and 0.9 V in 2 M Li₂SO₄ with those previously reported in the literature¹⁻⁵, showing a 20% increase for devices made according to the teachings of this application over the next best results. Finally, FIG. 4(e) a plot of power and energy densities per-area, which compares per-area CNF supercapacitor power and energy densities obtained using SCs made according to the present invention with previously reported results³⁻⁶. By utilizing the entire 3D Ni foam structure, mass loadings of ˜60 mg/cm² CNFs have been achieved, enabling superior per-area performance results. Furthermore, device stability was confirmed by charging/discharging cells over 3,000 cycles with an average Coulombic efficiency of 99.82%, this cycling data present at FIG. 6.

### EXAMPLE

### Deposition of the Alumina Layer

Recipe: A piece of nickel foam of approximately 1 cm×1 cm×0.2 cm was obtained and placed in an ALD reactor. The reactor was internally heated to 150° C., and a constant flow of N₂ at 50 sccm established within the reactor. Gas pulses of the following were then sequentially introduced: H₂ O for 0.015 s, wait 20 s, then pulse trimethyl aluminum (TMA) for 0.015 s, wait 20 s, and repeat for 10 cycles. A growth rate of 0.91 angstroms per cycle at 150° C. resulted. The presence of the water was used to convert the trimethyl aluminum to alumina (Al₂O₃), according to the following formulas where the asterisks represent the surface species:

AlOH*+Al(CH₃)3→AlOAl(CH₃)₂*+CH₄ (A)

AlCH₃*+H₂O→AlOH*+CH₄ (B)

In these studies, the alumina films were deposited using an ALD reactor. Each AB growth cycle consists of sequential exposure to TMA and H₂O. When TMA is introduced to the ALD reactor, it starts to react with the hydroxyl (—OH) groups on the substrate surface. When this surface reaction has completed, the remaining reactants and by-products are purged from the reactor. In the next step, H₂O vapor is introduced to the reactor. H₂O reacts with the methyl (—CH₃) groups on the surface until all the —OH groups have become regenerated. This is followed by another purging step after which the surface is ready for a new AB cycle. By repeating these AB cycles, a desired film thickness can be achieved.

ALD was chosen as the method of choice as it provides (1) very precise control of layer thickness, and (2) uniform, conformal coating of the surface. The primary disadvantage of this approach is that it is slow compared to other methods, such as CVD, electroplating, and the like. One skilled in the art will be familiar with such methods and should weigh the advantages and disadvantages of each and choose accordingly. For example, one consideration to take into account might be alumina's electronically insulating properties, which may make electroplating difficult.

### Supercapacitor Cell Preparation

For cell assembly, a separator (Whatman 8 μm filter paper) was sandwiched between two carbon nanofiber on nickel foam electrodes. The substrates were each in contact with platinum foil (Sigma-Aldrich) current collectors. The resulting assembly was sandwiched between two glass slides wrapped tightly by Parafilm and submerged in a beaker filled with a 2 M Li₂SO₄ aqueous electrolyte solution. SC measurements were carried out using a battery analyzer (MACCOR 4300).

### Data Analysis

In the reported galvanostatic data, the iR drop from the top cut-off potential and the slope of the discharge curve were used to obtain power and energy densities, respectively. The per-area power was calculated by using

P=(V²M)/[4R]

where V is the cut-off potential, R is the internal resistance, and M is the total mass of active electrode materials per centimeter squared. The internal resistance was determined from the voltage drop at the beginning of each discharge:

R=ΔV_{iR}/2i

where ΔV_{iR} is the voltage drop between the first two points from its top cut-off. This voltage drop is also referred to as the iR drop, with i the current applied.

The capacitance (Cₐ) per-area was calculated according to the formula

Cₐ=(im)/−[ΔV/Δt]=(im)/−(slope)

where i is the current applied, [ΔV/Δt] is the slope of the discharge curve after the initial iR drop, and m is the mass of active electrode materials on one electrode per centimeter squared. Similarly, energy density (E) was calculated using

E=0.5CV²M

Where V and M are the same notations as in the power calculation, and C is the measured capacitance.

It is important to note that all per-area calculations presented here are based on geometric device area rather than the total surface area of active electrode materials. It is believed that geometric device area is far more important for potential applications for future devices utilizing 3D metallic foam substrates, especially for small devices which have significant area restrictions or for stationary devices in which per-area performance characteristics are far more significant than those related to mass.

### TEM Characterization of Carbon Nanofibers

FIGS. 5(a) and 5(b) clearly illustrate that the thermal CVD growth process according to the method of this invention yields CNFs rather than carbon nanotubes for both small and large fibers, respectively. Also, the particulate Ni catalyst can be seen in FIG. 5(b).

### Supercapacitor Impedance Data and Capacity Retention

The Nyquist plot of FIG. 6(a) indicates an internal resistance of 2.5 Ω (X-intercept) and a resistance of 1.5 Ω inside the pores in the CNF structures. The 2.5 Ω result is consistent with the calculated iR-drop resistance in the charging and discharging voltage profiles of the devices [See FIG. 4(a)]. These impedance data showing relatively low resistivities further explains the high per-area power and energy densities of the SC of the invention, as the electrolyte ions can efficiently penetrate the space between adjacent CNFs during charging to contribute to double-layer capacitance throughout the entire 3D Ni foam network. During cycling tests the coulombic efficiency between charging and discharging was nearly 100% (99.82% average). These data show that side reactions are negligible and thus capacity fading with cycling is minimal.

In conclusion, supercapacitors with very high active material mass loadings and thus superior per-area capacitances, energy densities, and power densities have been described. Such was obtained by utilizing the entire surface area of CNFs on 3D metallic foam structures. Using an improved low-temperature thermal CVD CNF growth process, made possible by a thin alumina coating on pristine Ni foam, Ni₃C formation within the Ni foam backbone was minimized, the presence of Ni₃C not only deteriorating the SC performance but also increasing the brittleness of the SC electrodes.

More generally, other metal foams such as Copper, Cobalt, and the like may potentially be used as 3D metallic backbones for loading active SC materials. However, in the case of catalysis for CNF growth, Ni as a metal foam backbone is the more preferred embodiment.

During CVD formation of CNFs, H₂ should be present in the gas stream which forms the CNFs to avoid high temperature annealing steps that would otherwise be required to interconvert Ni to nickel oxide back to Ni to roughen the surface of the metal foam and allow non-planar growth sites. As mentioned above, in one embodiment ethylene is used in the gas stream during CNF formation process. However, many other hydrocarbons are also suitable. Some non-limiting examples include alcohols such as methanol or ethanol. In one embodiment methane can be used. In another more preferred embodiment, acetylene is used. Acetylene has the advantage of lowering the minimum temperature at which the process can be carried out. Using acetylene, the temperature range would be roughly within 300° C.-500° C.

At minimum, the pores of the nickel foam should be large enough to allow electrolyte solution penetration either by simple diffusion or via a capillary force mechanism. The maximum pore size should take into consideration the fact that as the pores become larger, less Ni foam surface area is available to be coated with CNFs. This could result in lower mass loading of the CNFs. Porosity should be optimized for different industrial applications.

The pore sizes of the alumina layer should be optimized so that the pores are not so large that Ni₃C begins to form in the Ni foam, but not so small that Ni is unable to diffuse through the alumina layer. The lower limit to the pore size is not easy to characterize because the pores in the alumina layer cannot be seen using electron microscopy (SEM). Nor can pore size distribution be accurately determined, even with advanced TEM. None the less, there is likely a distribution in the pore (or crack) sizes because they are formed from the thermal stresses that occur during heating and cooling of the samples. For industrial purposes, the sizes of the pores will likely depend on the heating and cooling rates during the ALD process and the CNF growth process. The temperature the sample reaches during the CNF growth process is significantly higher than the ALD process so the pore formation during CNF growth will be much more significant.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself

We claim:

1. A method for forming a composite of carbon nanofibers on a metal foam base comprising:
providing a metal foam base;
depositing one or more atomic layers of alumina over said metal foam base; and, thereafter forming carbon nanofibers on said alumina coasted metal foam base.

2. The method of claim 1 wherein the metal foam base is a nickel foam.

3. The article of claim 2 wherein the nickel foam has a porosity of about 95%.

4. The method of claim 1 wherein the deposition of the alumina over the metal foam base is performed using atomic layer deposition.

5. The method of claim 4 wherein the depositing step further includes the steps of:
establishing a constant flow of N₂ through an atomic layer deposition reaction chamber;
introducing a short pulse of H₂O into said atomic layer deposition reaction chamber;
continuing to flow N₂ for a predetermined interval of time;
introducing a short pulse of trimethyl aluminum into said reaction chamber;
continuing to flow N₂ for a second predetermined interval of time; and
repeating the above steps until the desired number of atomic layers of alumina has been obtained.

6. The method of claim 1 wherein the one or more deposited atomic layers of alumina contains multiple pathways allowing for the diffusion of metal from the foam to the surface of the alumina layer.

7. The method of claim 1 wherein the carbon nanofibers are formed by flowing a mixture of H₂, and C₂H₄ in an argon carrier gas into a CVD chamber maintained at an elevated temperature.

8. The method of claim 7 wherein the elevated temperature is maintained at above 410° C.

9. The method of claim 7 wherein the elevated temperature is maintained at between about 440° C. to 470° C.

10. The method of claim 7 in which the formation step is carried out for about 20 to 30 minutes.

11. A carbon nanofiber on metal foam composite made according to the method of claim 1.

12. The carbon nanofiber on metal foam composite of claim 10 wherein the carbon nano fibers are solid fibers.

13. A supercapacitor made using the carbon nanofiber on metal foam composite of claim 11.

14. The supercapacitor of claim 13 wherein a separator is sandwiched in between two carbon nanofiber on nickel foam electrodes, each electrode in contact with a current collector.

15. The supercapacitor of claim 13 further including an electrolyte disposed between the electrodes.

16. The supercapacitor of claim 15 wherein the electrolyte is an aqueous solution of Li₂SO₄.
